(19) United States
(12) Patent Application Publication
(10) Pub. No.: US 2012/0064700 A1
(43) Pub. Date: Mar. 15, 2012

(54) SEMICONDUCTOR SUBSTRATE, SEMICONDUCTOR DEVICE AND METHOD OF MANUFACTURING A SEMICONDUCTOR SUBSTRATE

(76) Inventors: Maxim Odnoblyudov, St. Petersburg (RU); Vladislav Bougrov, St. Petersburg (RU); Alexei Romanov, St. Petersburg (RU); Teemu Lang, Helsinki (FI)

(21) Appl. No.: 13/211,627

(22) Filed: Aug. 17, 2011

Related U.S. Application Data
(62) Division of application No. 11/792,687, filed on May 30, 2008.

(30) Foreign Application Priority Data
Dec. 14, 2004 (FI) FI 20045482
May 19, 2005 (FI) PCT/FI2005/000233

(51) Int. Cl. H01L 21/20

(52) U.S. Cl. 438/479; 257/E21.09

(57) ABSTRACT

A semiconductor substrate of the present invention is made of nitrides of group III metals having wurtzite crystal structure and is grown in vapor phase either on a (0001) oriented foreign substrate (2), lattice mismatched to the semiconductor substrate materials, or on existing (0001) oriented highly dislocated layer (3) of the semiconductor substrate materials and has a highly reduced dislocation density. According to the present invention, a structure is utilized for the dislocation density reduction, which comprises a dislocation redirection layer (4) providing intentional inclination of threading dislocations (6) towards high index crystallographic planes having crystallographic indexes other than (0001) and those of the type {1 1̅00}, in order to enhance the probability for dislocation reactions; and a dislocation reaction layer (5) positioned above said dislocation layer (4), in which the threading dislocations (6) coalesce with each other resulting in reduced threading dislocation density at the semiconductor substrate surface (7).

This application is a divisional filing of U.S. application Ser. No. 11/792,687, filed May 30, 2008, the disclosure of which is incorporated herein by reference.

### FIELD OF THE INVENTION

The invention relates in general to a semiconductor substrate with reduced threading dislocation density. More particularly, the semiconductor substrate is formed of nitrides of group III metals with wurtzite crystal structure and grown in vapor phase either on a (0001) oriented foreign substrate, lattice mismatched to the semiconductor substrate materials, or on existing (0001) oriented highly dislocated layer formed of the semiconductor substrate materials. The invention also relates to a device utilizing and a method of manufacturing such substrate.

### BACKGROUND OF THE INVENTION

Growth of (0001) oriented nitrides of group III metals with wurtzite crystal structure on a foreign substrate with large lattice mismatch, e.g. sapphire, silicon carbide, silicon, or zinc oxide, occurs via formation of three-dimensional islands on the surface of the substrate. Usually, as the first step, a thin layer is deposited on the substrate at a low temperature. This layer is continuous but possesses a nanosize polycrystalline structure. The layer consists of a mixture of cubic and hexagonal phases. Afterwards, the temperature is raised up to the typical growth temperature and recrystallization of the nucleation layer occurs. During recrystallization, the continuous two-dimensional layer is destroyed and three-dimensional islands of the material in hexagonal phase are formed and grow on the substrate surface as a result of mass transfer through the gas phase. The islands typically have a pyramidal shape. The crystal lattice mismatch at the layer-substrate interface is the reason for the formation of misfit dislocations (MDs) with dislocation lines directed along the interface. These MDs relax elastic strain associated with mismatch and are not harmful for device structures. The island interior at the initial stage of recrystallization is essentially dislocation free and may contain only a small amount of threading dislocations (TDs). The islands demonstrate also twist misorientation of their crystal lattice about the [0001] growth direction. The transition to 2D planar growth mode can be achieved through further growth and coalescence of the islands. Due to misorientation of the islands, TDs of mainly edge type are formed at the boundaries of the merging islands. The density of TDs in real III-nitride films can be as high as 10 cm⁻². The vertical TDs propagate through the layer during further growth without reactions and remain in the working zone of electronic and optoelectronic devices. It is known that the presence of such high TD density changes device physical performance. Despite of their high density, TDs are essentially non-equilibrium defects. Therefore their number can be reduced by appropriate material treatment or the choice of growth conditions. During recent years a large amount of experimental researches and practical inventions have been directed to reduce TD densities in III-nitrides.

Method of growth of crystalline epilayers on a lattice mismatched substrate via deposition of thin low temperature layer was disclosed by J. Matthews and W. Stobbs in U.S. Pat. No. 4,174,422. In case of AlₓGa₁₋ₓN films, it was disclosed by I. Akasaki and N. Sawaki in U.S. Pat. No. 4,855,249. Typical TD density achieved in the epitaxial layers of nitrides of group III metals with wurtzite crystal structure grown on low temperature layers is ˜10⁹ cm⁻². Different variations of the method constitute a significant part of the patents devoted to the initiation of nitrides of group III metals growth on a foreign substrate; see e.g. K. Manabe et al in U.S. Pat. No. 5,122,845; S. Nakamura in U.S. Pat. No. 5,290,393; Y. Ohba and A. Hatano in U.S. Pat. No. 5,656,832. It has been also shown by H. Kawai et al in U.S. Pat. No. 5,863,811 that using several low temperature layers can decrease the TD density.

Several other techniques for reduction of dislocation density in crystalline epilayers grown on a lattice mismatched substrate were suggested. T. Mishima et al. in U.S. Pat. No. 5,633,516 suggested using graded lattice constant buffer layers. J. Bean et al. in U.S. Pat. No. 5,091,767 suggested using “dislocation sinks”, amorphous regions of the layer, on the substrate, in which dislocations are annihilated while propagating in the amorphous material. H. Morkoc in U.S. Pat. No. 6,657,232 disclosed a defect filter, comprising islands of one material formed on the underlying material and a continuous layer of a second material over the islands.

The most effective methods found up to now to reduce TD density in epitaxial layers grown on foreign substrates are selective area growth (SEA) and epitaxial lateral overgrowth (ELO) of a layer over a predeposited dielectric mask through openings in it. The first discussion of the principal features of selective epitaxy of semiconductors such as GaAs on Si to our best knowledge was given by D. Morrison and T. Daud in the U.S. Pat. No. 4,522,661. A lot of papers were devoted to SEA and ELO of various conventional III-V semiconductors on highly mismatched substrates. It was reported by D. Kapolnek et al. (Appl. Phys. Lett. 71(9), 1204 (1997)) that there exists high anisotropy in growth of GaN on a sapphire substrate by SEA using linear mask patterns. Vertical and lateral growth rates were reported to have opposite orientation-related minima and maxima, with hexagonal symmetry. The possibility of selective growth of gallium nitride hexagonal microprisms on a (0001) sapphire substrate has been successfully demonstrated by T. Akasaka et al. (Appl. Phys. Lett. 71(15), 2196 (1997)). ELO variations were demonstrated by A. Sakai et al. (Appl. Phys. Lett. 71(16), 2259 (1997)), T. Zheleva et al. (Appl. Phys. Lett. 71(17), 2472 (1997)), and R. Davis et al. in U.S. Pat. No. 6,051,849. It was found by M. Coltrin et al. (MRS Internet J. Nitride Semicond. Res. 4S1, G6.9 (1999)) that ELO feature morphology is influenced also by the mask fill factor. Besides, it was demonstrated by J. Park et al. (Appl. Phys. Lett. 73(3), 333 (1998)) that the vertical growth rate is strongly dependent on both the orientation of mask stripe opening and the fill factor, while the lateral overgrowth is relatively weakly dependent on the fill factor, but depends strongly on the stripe orientation.

In the majority of variations of these techniques, see e.g. U.S. Pat. No. 5,880,485 by D. Marx et al., U.S. Pat. No. 6,252,261 B1 by A. Usui et al., propagation of TDs above the masked regions is blocked by the mask (see FIG. 2a) and the crystalline quality of the epitaxial semiconductor layers grown by these methods can be improved drastically. However dislocation-free areas in this case are limited to the narrow stripes above dielectric stripes. Additionally, new dislocations are generated in the regions, where overgrowth wings from neighboring openings meet, because of the phenomena of crystal lattice tilt in the wing regions, see e.g. P. Fini et al. (J. Cryst. Growth 209, 581 (2000)) and A. Romanov et al. (J. Appl. Phys. 93(1), 106 (2003)). Therefore these techniques can only be used for narrow devices like laser diodes. An improved variation of the ELO technique was suggested by P. Vennegues et al. (J. Appl. Phys. 87(9), 4175 (2000)). It provides the growth modes, which ensure dislocation bending during the lateral overgrowth so that their line direction becomes parallel to the layer-substrate interface (see FIG. 2b). In result, further propagation of the dislocations normal to the epilayer surface is prevented. One of the disadvantages of these variations is that they are ex situ processes. There exist several variations of the SEA and ELO techniques, such as pendeo epitaxy, see e.g. U.S. Pat. No. 6,177,688 by K. Linthicum et al., and cantilever epitaxy, see e.g. U.S. Pat. No. 6,599,362 by C. Ashby et al. and T. M. Katona et al. (Appl. Phys. Lett. 79(18), 2907 (2001)), which constitute a significant part of the patents devoted to the dislocation reduction in nitrides of group III metals heteroepitaxy.

Among in situ techniques, the most efficient one is depositing a dielectric material on the substrate or the bottom epitaxial layer, which produces partial random coverage, i.e. micromasking, of the epilayer surface area by an interlayer of submonolayer thickness (see e.g. U.S. Pat. No. 6,610,144 by U. Mishra and S. Keller). Dielectric material deposited can be e.g. silicon nitride, silicon dioxide or magnesium nitride. It acts as an antisurfactant facilitating three dimensional growth mode in the uncovered substrate regions. The growth of epitaxial film then proceeded via lateral overgrowth of the dielectric covered regions, similar to ELO technique. Part of dislocations either become blocked by the micromask or bended during lateral overgrowth over micromasked regions (see e.g. U.S. Pat. No. 6,802,902 by B. Beaumont at al.) and become parallel to the substrate surface. The efficiency of these techniques is limited by the fact that the mask regions are distributed randomly and do not provide selective treatment of the dislocated regions. The efficiency is also less for the less dislocated layers.

A dislocation reduction technique, which pro vides selective treatment of the dislocations, is disclosed by N. Ledentsov in US Patent Application 20020167022A1. Variations of this technique are also disclosed by R. Croft at al. in patent application WO 2004/008509 A1.

According to the preceding prior art description, despite of all development in the area the known solutions still have plenty of drawbacks and weaknesses. There is an evident need for a substrate formed of nitrides of group III metals having highly reduced dislocation density throughout its surface. Specially, there is a need for an effective, controllable, entirely in situ method of manufacturing such substrates with a surface quality suitable for further epitaxial growth of semiconductor device layers.

### PURPOSE OF THE INVENTION

The purpose of the invention is to eliminate the above-referred disadvantages of the prior art.

Specifically, the purpose of the invention is to disclose a new type of semiconductor substrate with highly reduced threading dislocation density and surface suitable for epitaxial growth, the substrate being formed of nitrides of group III metals having wurtzite crystal structure and grown in vapor phase either on a (0001) oriented foreign substrate, lattice mismatched to the semiconductor substrate materials, or on existing (0001) oriented highly dislocated layer of the semiconductor substrate materials.

Further, the purpose of the invention is also to disclose a new type of semiconductor device comprising a semiconductor substrate described above.

Finally, the purpose of the invention is also to disclose a new, effective and well controllable in situ method for manufacturing semiconductor substrate of type described above.

### SUMMARY OF THE INVENTION

The semiconductor substrate in accordance with the invention is characterized by what is presented in claim 1. The substrate is formed of nitrides of group III metals having wurtzite crystal structure and grown in vapor phase either on a (0001) oriented foreign substrate, lattice mismatched to the semiconductor materials, or on existing (0001) oriented highly dislocated layer of the semiconductor substrate materials. Most typical nitrides used are GaN and AlₓGa₁₋ₓN, 0<x≦1, but also other materials like In_{y}Ga_{1-y}N, 0<y≦1, and BN can be used. According to the present invention, the semiconductor substrate comprises a dislocation redirection layer, in which inclination of threading dislocations towards high index crystallographic planes, characterized by indexes other than (0001) and those of the type {1 1̅00}, is arranged in order to enhance the probability of the threading dislocations to meet each other; and a dislocation reaction layer positioned above said dislocation redirection layer, in which the threading dislocations coalesce with each other resulting in reduced threading dislocation density at the semiconductor substrate surface. Such a surface with reduced dislocation density is of high crystalline quality and well suitable for further epitaxial growing of device layers on it. The dislocation density is reduced throughout the surface in contrast to the prior art substrates with dislocation density reduction carried by partial masking the highly dislocated layer at initial stages of the substrate growth.

A semiconductor device in accordance with the present invention is characterized by what is presented in claim 4. The semiconductor device is made of nitrides of group III metals having wurtzite crystal structure and grown in vapor phase either on a (0001) oriented foreign substrate, lattice mismatched to the semiconductor device materials, or on existing (0001) oriented highly dislocated layer of the semiconductor device materials. The device comprises a semiconductor substrate and device layers positioned above said substrate. According to the present invention, the semiconductor substrate comprises a dislocation redirection layer, in which inclination of threading dislocations towards high index crystallographic planes, having indexes other than (0001) and those of the type {1 1̅00}, is arranged in order to enhance the probability of the threading dislocations to meet each other; and a dislocation reaction layer, in which the threading dislocations coalesce with each other resulting in reduced threading dislocation density at the semiconductor substrate surface. The semiconductor device can be e.g. a LED or a laser diode. Clear advantages are achieved with this structure in form of better quality of the device layers due to the low dislocation density throughout the semiconductor substrate surface.

Said inclination of the threading dislocations in accordance with the present invention can be achieved for example by development of crystallographic plane facets with crystallographic indexes other than (0001) and those of the type {1 1̅00}. The inclination is then governed by diminishing of the dislocation energy, when the dislocation becomes perpendicular to an intentionally introduced high index facet plane, comparing with the energy of the threading dislocation with dislocation line along [0001] crystal axis. This results from the proportionality between the energy of dislocation and its length. Additionally, dislocations having Burgers vector equal to one of the three basal plane translations±⅓<2 1̅1̅0>, have a maximal energy per unit length (described by the energy factor) when their line directions are parallel to [0001], i.e. for the case of edge dislocations with line direction parallel to the c-axis of the wurtzite elementary cell. This favors to the process of inclination of [0001] edge threading dislocations to the energetically more favorable position. Locally the change in the direction of the dislocation line is driven by the configuration force, which is caused by the interaction of a dislocation with a free surface. The inclination of initially oriented dislocations significantly increases their probability to interact and react with each other. As a result of such interaction annihilation of two dislocations with opposite Burgers vector or fusion of two dislocations to produce a single TD will take place. Both these processes provide the decrease of the dislocation density.

Preferably, the dislocation redirection layer according to the present invention has a thickness of 0.2-4 μm in order to assure effective inclination of the threading dislocations. The dislocation reaction layer in accordance with the present invention has preferably a thickness of 1-10 μm to provide sufficient amount of dislocation reactions.

The method of the present invention of manufacturing a semiconductor substrate is characterized by what is presented in claim 7. The physical basis of the developed approach is to force the inclination of initially vertical threading dislocations to enhance probability of dislocation reactions. The semiconductor substrate is made of nitrides of group III metals having wurtzite crystal structure and grown in vapor phase either on a (0001) oriented foreign substrate, lattice mismatched to the semiconductor substrate materials, or on existing (0001) oriented highly dislocated layer of the semiconductor substrate materials. Said nitrides can be e.g GaN, AlₓGa₁₋ₓN with 0<x≦1, In_{y}Ga_{1-y}N with 0<y≦1, and ON. The vapor-phase growth processes can be executed with a vapor-phase epitaxy reactor like metal organic vapor-phase epitaxy or hydride vapor-phase epitaxy. According to the present invention, the method comprises steps of growing a dislocation redirection layer on said foreign substrate or said existing highly dislocated layer, the growing providing intentional inclination of threading dislocations towards high index crystallographic planes, having crystallographic indexes other than (0001) and those of the type {1 1̅00}, in order to enhance the probability of the threading dislocations to meet and react with each other; and growing a dislocation reaction layer above said dislocation redirection layer facilitating threading dislocation reactions, the growing facilitating reactions between the threading dislocations, thereby reducing the dislocation density. The method of the present invention, in contrast to the methods disclosed in prior art utilizing bending or filtering of individual threading dislocations, considers the kinetics of threading dislocations ensemble and facilitates reactions among interacting threading dislocations targeting efficient dislocation density reduction throughout the surface of the final substrate.

The important step for implementing the present method, providing said inclination, for any reactor is providing preferential growth of crystallographic plane facets with crystallographic indexes other than (0001) and those of the type {1 1̅00} for initiating growth of the dislocation redirection layer. By preferential growing or preferential growth here and elsewhere in this document a growing process is meant in which the process parameters such as e.g. time, temperature, gas flows and pressure are chosen to produce growth of facets with specific crystallographic indexes. For each reactor such parameters exist. However, each reactor has its own exact individualistic parameters so that no generic set of parameter values can be given. Preferably, growing of the dislocation redirection layer is started with formation of precipitates on the surface of the foreign substrate or the existing highly dislocated layer, said precipitates having a height of 0.1-1.5 μm and surface density of 10⁷-10⁸ cm⁻²; and the growing of said dislocation reaction layer comprises preferential growing of crystallographic plane facets with crystallographic index (0001). Formation of said precipitates makes it possible to provide the inclination of the threading dislocations towards said high index crystallographic planes by further preferential growing of such high index plane facets. During said preferential growing of (0001) plane facets of the dislocation reaction layer the inclination, which enhances the reaction probability, is maintained. For each individual reactor process parameters for formation of precipitates of said type are individualistic and no generic set of parameter values can be given.

In general, the precipitates are formed during low-temperature deposition of the material with subsequent recrystallization at higher temperature. However, such technique typically results in forming a number of small precipitates with high density tending to merge before reaching the required height. According to the present invention, preferably, but not exclusively, the precipitates are formed during a sequence of short low-temperature depositions, performed in temperature range of 450-700° C., followed by high-temperature layer annealing periods, performed in temperature range of 900-1150° C. Accurate temperatures depend on the materials and reactor type used.

Duration of said short low-temperature depositions can be e.g. some dozens of seconds. During each annealing a part of deposited material is removed from the surface. Process parameters during annealing, such as temperature gradient and annealing time, are chosen to totally remove small precipitates while save large ones. In result, the dominant growth of only the largest precipitates occurs. This results in possibility to obtain precipitates with controlled height and density.

In one preferred embodiment of the method of the present invention the growing of said dislocation redirection layer comprises the steps of 1) formation of said precipitates on the surface of said foreign substrate or said existing highly dislocated layer; and 2) preferential growing of crystallographic plane facets with crystallographic indexes other than (0001) and those of the type {1 1̅00}. For the initially vertical threading dislocations locating mainly in the boundaries of the merged precipitates, it is energetically favorable to change their direction of propagation during further growth, which provides increasing areas of the high index facets. The theory of this process is explained earlier in this document. In result, the necessary conditions for reactions among inclined TDs are achieved. During preferential growth of (0001) facets of the dislocation reaction layer the enhanced probability of dislocation reactions is maintained.

In another preferred embodiment of the method of the present invention growing of said dislocation redirection layer comprises the steps of 1) formation of said precipitates on the surface of said foreign substrate or said highly dislocated layer; 2) preferential growing of crystallographic plane facets with crystallographic indexes other than (0001) and those of the type {1 1̅00}; 3) in situ deposition of amorphous material into the surface potential minima located in grooves; and 4) preferential growing of crystallographic plane facets with crystallographic indexes other than (0001) and those of the type {1 1̅00}. By in situ depositing amorphous material on the surface potential minima enhanced inclination of the dislocations can be facilitated. The second step is stopped as tong as merging of the precipitates of the semiconductor material formed on substrate surface starts to occur. Threading dislocations of the edge type are formed at the boundaries of the merging precipitates. At this stage of growth, the emerging positions of these edge type threading dislocations are mostly located in the grooves between the neighboring precipitates. The next step of the process comprises in situ deposition of amorphous material. Due to surface diffusion assisted kinetics, the atoms of the amorphous material tend to arrive to the surface potential minima located in the grooves. At this phase, the threading dislocations stay at the interface between the amorphous material and the semiconductor material, because presence of the amorphous material decreases potential barrier for dislocation inclination. The amount of amorphous material deposited should be chosen to ensure the dislocations to stay inclined during subsequent growth of the dislocation reaction layer. The optimal amount depends on materials used and can be e.g. chosen to provide coverage from 5 to 70% of the groove height. During further growth, which provides increasing areas of the high index facets, the threading dislocations will stay inclined tending to direct towards said high index planes. During the growth of the dislocation reaction layer with preferential growing of (0001) facets the dislocations stay inclined thus maintaining the enhanced probability for dislocation reactions. In result, a compact low dislocation density semiconductor substrate is obtained.

In a third preferred embodiment of the method of the present invention growing of said dislocation redirection layer comprises the steps of 1) formation of the precipitates on the surface of said foreign substrate or said highly dislocated layer; 2) preferential growing of crystallographic plane facets with crystallographic index (0001); 3) in situ selective chemical etching of the regions on the layer surface close to the dislocation cores; 4) in situ deposition of amorphous material into the surface potential minima located in the etch pits; 5) preferential growing of crystallographic plane facets with crystallographic indexes other than (0001) and those of the type {1 1̅00}. The selective etching means that when chemically etching the surface of the highly dislocated layer by a proper gas mixture the regions close to the dislocation cores are etched at a higher rate. This leads to the formation of etch pits at the end of the dislocation lines, which act similar to the grooves resulting from incomplete coalescence of the precipitates. The gas mixture can comprise e.g. ammonia, silane and hydrogen. During the next stage of in situ deposition of amorphous material, due to surface diffusion assisted kinetics, the atoms of the amorphous material tend to arrive to the surface potential minima located in the etch pits. At this phase, the threading dislocations stay at the interface between the amorphous material and the semiconductor material, because presence of the amorphous material decreases potential barrier for dislocation inclination. The amount of amorphous material deposited should be chosen to ensure the dislocations to stay inclined during subsequent growth of the dislocation reaction layer and it depends on materials used. During further growth, which provides increasing areas of the high index facets, the threading dislocations will stay inclined tending to direct towards said high index planes. During the growth of the dislocation reaction layer with preferential growing of (0001) facets the dislocations stay inclined thus maintaining the enhanced probability for dislocation reactions. In result, a compact low dislocation density semiconductor substrate is obtained.

Said amorphous material in said preferred embodiments can be e.g. SiN but there are also other alternatives. The process parameters of the in situ deposition are equipment specific and can be different for each individual reactor, so that no generic parameter values can be given.

Said preferred embodiments of the inventive method have clear advantages in comparison with other methods involving deposition of dielectric materials for dislocation masking. The present invention allows in situ deposition of the masking material predominantly to the areas where the dislocation lines are terminated, whereas other methods provide random coverage of the surface. The essential feature of these embodiments of the invention is using the localization of threading dislocations in the surface grooves at intermediate stage of growth.

The thicknesses of the layers of the present invention will now be discussed in more detail. The required thicknesses depend on the targeted threading dislocation density. The thickness of the dislocation redirection layer should provide merging of the precipitates in the continuous film. Preferably it is in the range from 0.2 to 4 μm. This thickness provides large enough areas of the high index facets. Preferably, the thickness of the dislocation redirection layer is 2-3 times more than the precipitate height. The thickness of the dislocation reaction layer is preferably 1-10 μm. According to the approach used in the present invention, reduction of the total dislocation density ρ=ρᵥρᵢ, which is subdivided into the density ρᵥ of the vertical TDs and the density ρᵢ of the inclined TDs, can be determined from the following system of “reaction-kinetic” equations:

$$\{ \begin{matrix}\frac{d {ρ}_{v}}{d h} = - {f}_{redirection}^{v} ( {ρ}_{v} , {ρ}_{i} ) - {f}_{reaction}^{v} ( {ρ}_{v} , {ρ}_{1} ) ; \\ \frac{d {ρ}_{i}}{d h} = + {f}_{redirection}^{i} ( {ρ}_{v} , {ρ}_{i} ) - {f}_{reaction}^{i} ( {ρ}_{v} , {ρ}_{i} ) .\end{matrix}$$

Here h is the layer thickness and it plays a role of evolution variable; the functions in the right hand sides f_{redirection}^{v}, f_{redirection}ⁱ and f_{reaction}^{v}, f_{reaction}ⁱ describe the processes of vertical dislocations redirection, their transformation into inclined dislocations and the reactions between them, correspondingly. These functions depend on the chosen method for substrate manufacturing and therefore include (in parameterized form) dependence on the growth conditions and masking process. They also explicitly include layer thickness and parameters describing the intensity of dislocation reactions.

For example, the above functions can be chosen as

$${f}_{redirection}^{v} = {f}_{redirection}^{i} = \frac{1}{p} \frac{{ρ}_{v}}{h} ,$$

f_{reaction}^{v}=0, and f_{reaction}ⁱ=κ·ρᵢ². For such parameterization, p is related to the angle α between the facet planes in the redirection layer and (0001) crystal plane via p=1/γ·cos α/(1−cos α) with γ being the coefficient, which depends on crystal structure and additional factors that strengthen inclination of the vertical dislocations, such as presence of an amorphous material at the crystallite surface, κ is the TD reaction cross-section parameter. Increase of γ (e.g. by deposition of amorphous material) results in faster decrease of density of vertical TDs with thickness. It is important to note that TD density reduction rate depends on the initial TD density. Higher initial TD density leads to faster TD density reduction rate. It results from the fact that at higher TD densities TDs have higher probability to meet and react.

The present invention provides essential advantages compared to the prior art. The substrate according to the invention can have drastically reduced threading dislocation density throughout the surface and is thus well suitable for further epitaxial growth of device layers. The manufacturing method of the invention includes only in situ process steps while many variations of traditional methods necessitate unwanted ex situ processing. The method of the invention is also well controllable in contrast to e.g. micromasking method of the prior art including random mask coverage.

### BRIEF DESCRIPTION OF THE DRAWINGS

The accompanying figures, which are included to provide a further understanding of the invention and constitute a part of this specification, illustrate embodiments of the invention as well as prior art examples and together with the description help to explain the principles of the invention.

FIG. 1 shows a schematic cross sectional view of a semiconductor substrate and a semiconductor device according to the present invention.

FIG. 2 represents schematic cross sectional views of films grown by prior art methods.

FIG. 3 is a schematic cross sectional view of the dislocation redirection layer according to the present invention at an intermediate stage of the layer growing.

FIG. 4 is a schematic cross sectional view of the dislocation redirection layer according to another embodiment of the present invention at an intermediate stage of the layer growing.

FIG. 5 is a schematic cross sectional view of a completed semiconductor substrate manufactured according to one embodiment of the present invention.

FIG. 6 shows one embodiment of the method of the present invention as a flow chart.

FIG. 7 presents atomic-force microscopy images of semiconductor precipitates at initial stages of growth of the dislocation redirection layer.

FIGS. 8 and 9 represent calculated TD densities in the substrates in accordance with the present invention.

FIG. 10 shows atomic-force microscopy images of a conventional substrate and a substrate according to the present invention.

### DETAILED DESCRIPTION OF THE INVENTION

Reference will now be made in detail to the embodiments and examples relating to the present invention, which are illustrated in the accompanying figures.

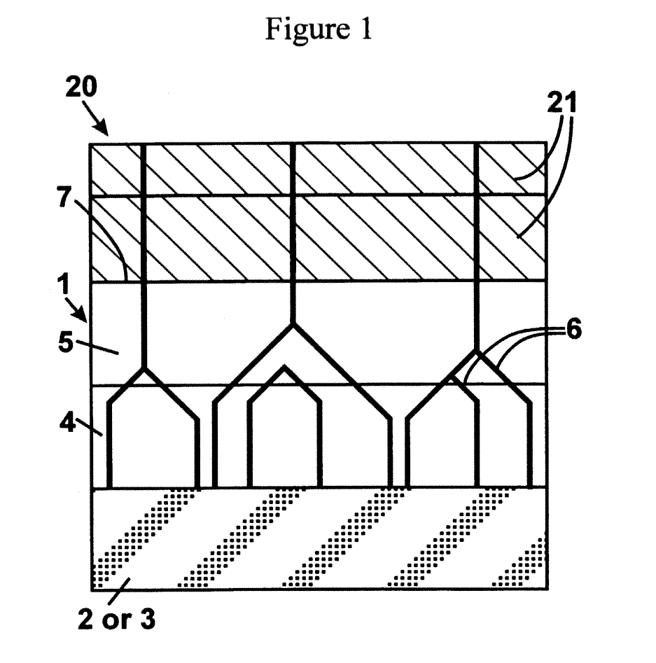

The semiconductor device 20 of FIG. 1 comprises a semiconductor substrate 1. Semiconductor substrate includes a foreign substrate 2 or a highly dislocated layer 3 of the semiconductor substrate materials, a dislocation redirection layer 4 and a dislocation reaction layer 5. Device layers 21 are grown on the semiconductor substrate surface 7. Threading dislocations (TDs) 6 formed in the early stage of the dislocation redirection layer 4 growth deviate upper in the layer from the initially vertical orientation. In the dislocation reaction layer 5 TDs 6 coalesce with each other thus reducing the dislocation density of the semiconductor substrate 1. As result, the semiconductor substrate surface 7 is of high crystalline quality with a low dislocation density and as such well suitable for further growing of the device layers 21.

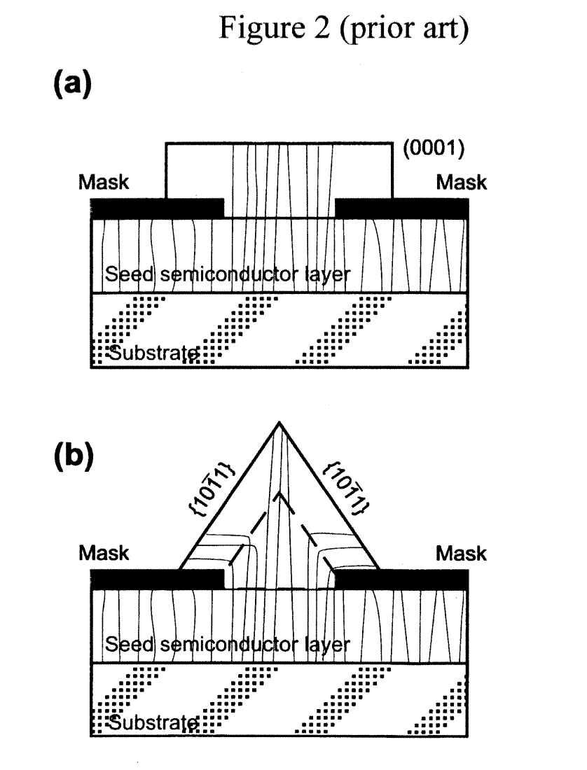

Prior art solutions illustrated in FIGS. 2a and 2b have inclusions of masks of amorphous material grown using different variations of SAE and ELO techniques. Dielectric masks are used to block the propagation of a part of the dislocations illustrated as essentially vertical, narrow lines. As shown in FIG. 2a, this may lead to dislocation-free areas above the mask. In an improved technique of FIG. 2b part of the TDs passed the mask are bent becoming parallel to the layer-substrate interface thus reducing the TD density at the upper layers. Though reducing the average TD density, these methods necessitate ex situ process steps, which complicate the manufacturing process.

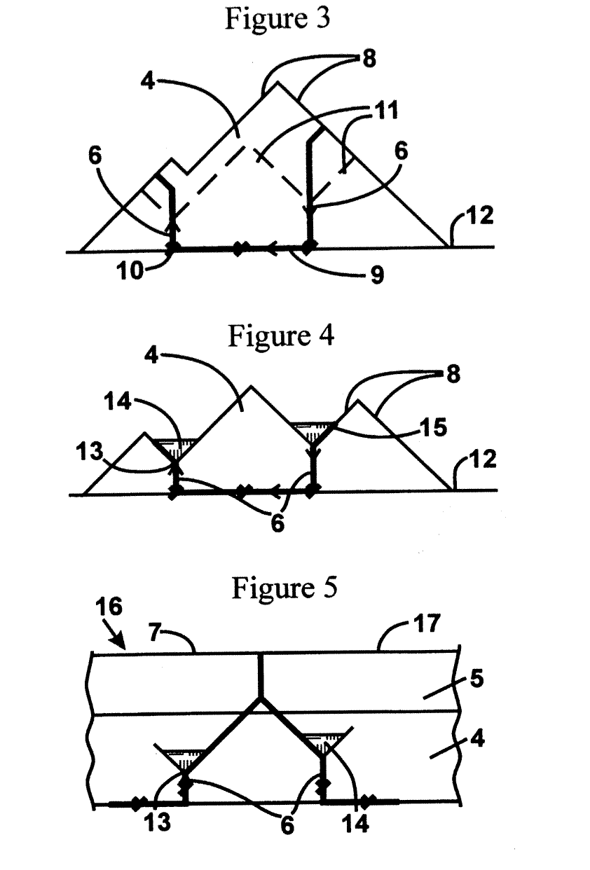

FIG. 3 shows edge TDs' 6 inclination from initially vertical orientation towards high index plane facets B during the growth of the dislocation redirection layer 4. The inclination enhances the probability of TDs 6 to react with each other during later growth of the dislocation reaction layer. A misfit dislocation 9 and direction of Burgers vector 10 are also shown in the figure. Direction of dislocation lines is represented by arrows. Dashed line represents merged semiconductor material precipitates 11 with edge type TDs 6 at the precipitate boundaries. The dislocation redirection layer 4 has been grown on the surface 12 of a foreign substrate or a highly dislocated layer of the semiconductor substrate materials.

In the dislocation redirection layer 4 illustrated in FIG. 4 grooves 13 between neighboring precipitates are filled with amorphous material 14. This amorphous material in the surface potential minima decreases potential barrier for dislocation inclination and TDs 6 stay at the interface 15 between the amorphous and the semiconductor materials. During further growth of the high index plane facets TDs will stay inclined.

Flat film 16 of FIG. 5 consisting of a dislocation redirection layer 4 grown with preferential growing of high index facets 8, and a dislocation reaction Layer 5 grown with preferential growing of (0001) facets 17 has inclusions of amorphous material 14 grown into the surface potential minima located in the grooves 13. The TDs 6 with inclined orientation caused by the amorphous material in the dislocation redirection layer 4 have later in the dislocation reaction layer 5 reacted with each other thus reducing the TD density at the surface 7 of the complete semiconductor substrate.

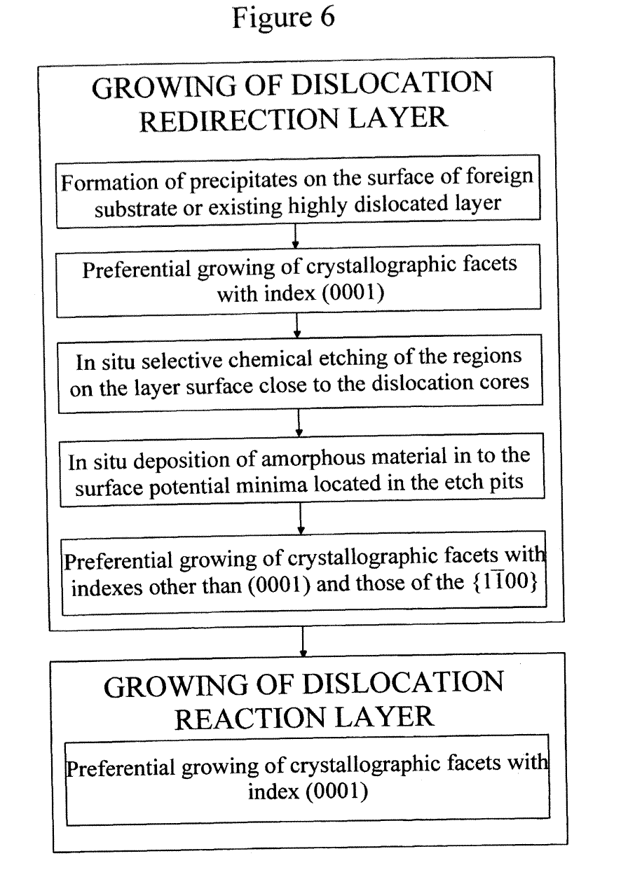

The manufacturing method illustrated in FIG. 6 has two main phases. At first, a dislocation redirection layer is grown. This phase consists of five sequential steps producing finally a layer with TDs deviated from initially vertical orientation. The first step is formation of the precipitates on the surface of the foreign substrate or the existing highly dislocated layer of the semiconductor substrate materials. The second step is preferential growing of crystallographic plane facets with crystallographic index (0001). Selective chemical etching of the region on the layer surface close to the dislocation cores is third step. Fourth step utilizes deposition of amorphous material into the surface potential minima located in the etch pits in order to facilitate the inclination of the TDs. The last step is again preferential growing of crystallographic plane facets with crystallographic indexes other than (0001) and those of the type {1 1̅00}. As a second phase dislocation reaction layer is grown where TDs with inclined orientation react with each other thus reducing the TD density.

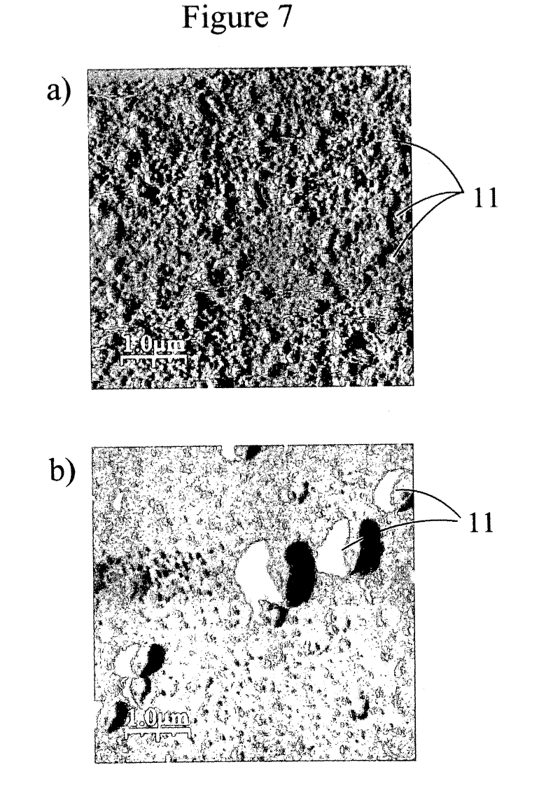

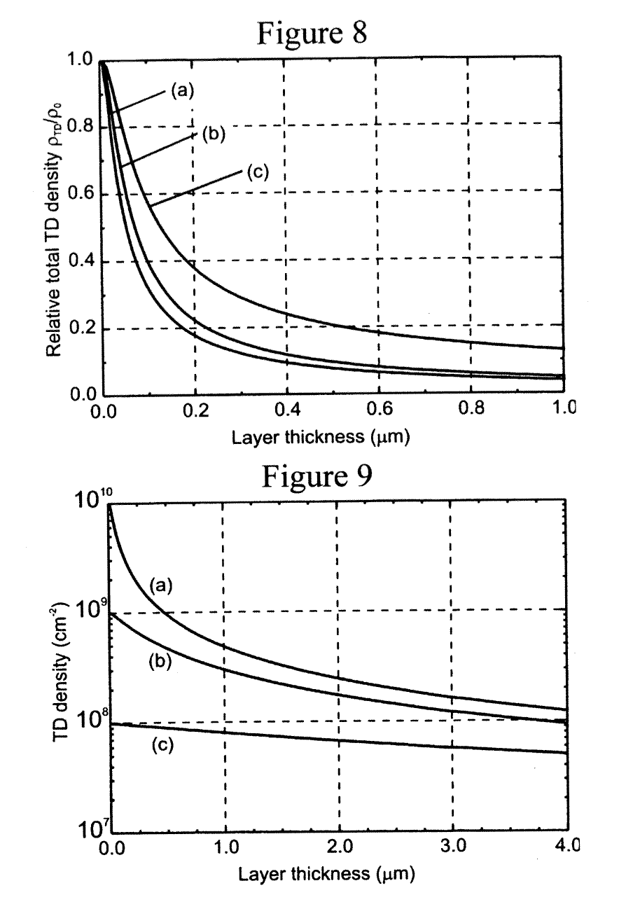

FIG. 7 illustrates the effect of precipitate 11 formation process consisting of a sequence of short low-temperature depositions followed by high-temperature layer annealing. The experiments were made on 3×2″ Thomas Swan Scientific Equipment Closed Coupled Showerhead reactor for GaN growth on sapphire substrate. In (a) presents the surface of the GaN layer after single standard deposition/annealing cycle, with average precipitate height of about 50 nm. Situation after double deposition/annealing cycle is shown in image (b), the average precipitate height is about 250 nm. The process parameters for (a) were as follows. Deposition: 120 s at 560° C.; annealing: 230 s at temperature ramp up to 1040° C. The process parameters for (b) were as follows. First deposition: 70 s at 530° C.; first annealing: 300 s at temperature ramp up to 1000° C.; second deposition: 90 s at 530° C.; second annealing: 300 s at temperature ramp up to 1040° C.

Calculated dislocation density in GaN epitaxial layer grown on a foreign substrate and having initial density of TD ρ₀=10¹⁰ cm⁻² is shown as function of the total layer thickness in figure B. The total layer thickness (“layer thickness” in the figure) means the thickness of the whole two-layer structure. The typical value for the dislocation reaction cross-section parameter in GaN was taken equal to 100 nm. Three values of the model representative parameter p were used: (a) p=0.5, (b) p=1, (c) p=2.

FIG. 9 presents calculations of the total TD density as function of the total GaN film thickness for three values of the initial TD density σ₀: a) 10¹⁰ cm⁻², b) 10⁹ cm⁻² and c) 10 cm⁻². The total film thickness (“layer thickness” in the figure) means the thickness of the whole two-layer structure. It was assumed that p=1. The curves of the FIG. 9 show the effect of the initial TD density on the TD density reduction rate. The higher is the initial density the higher is the reduction rate.

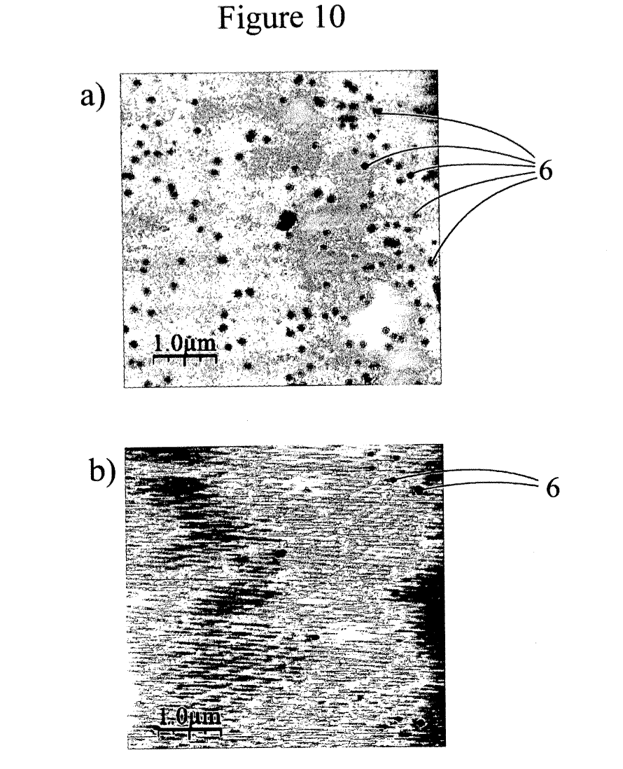

The experiments on the layers with initial TD density of about 10⁹ cm⁻² showed the reduction of TD density to less than 10⁸ cm⁻² after growth of GaN layers of 4 μm total thickness according to the present invention. FIG. 10 represents atomic-force microscopy images of two GaN layers grown on sapphire substrates using (a) conventional method of initial deposition of thin low temperature layer and (b) method according to the present invention. For the sample grown according to the present invention, experiments were made on 3×2″ Thomas Swan Scientific Equipment Closed Coupled Showerhead reactor for GaN growth on sapphire substrate. The process parameters for the formation of the precipitates were the same as in the experiments described for FIG. 7. Further preferential growth of crystallographic plane facets with crystallographic indexes other than (0001) and those of the type {1 1̅00} was carried at temperature of 1040° C. at TMG flow of 45 sccm and ammonia flow of 960 sccm. The dislocation reaction layer was grown at temperature of 1040° C. at TMG flow of 60 sccm and ammonia flow of 4500 sccm. Both samples were etched at 240° C. for 5 minutes in 50:50 mixture of ortho-phosphoric and sulfuric acids to show up density of TDs in the layers. The figures illustrate the efficiency of the present invention in reducing the TD 6 density.

It is obvious to a person skilled in the art that with the advancement of technology, the basic idea of the invention may be implemented in various ways. The invention and its embodiments are thus not limited to the examples described above; instead they may vary within the scope of the claims.

1. (canceled)

2. (canceled)

3. (canceled)

4. (canceled)

5. (canceled)

6. (canceled)

7. A method of manufacturing a semiconductor substrate made of nitrides of group III metals having wurtzite crystal structure and grown in vapor phase either on a (0001) oriented foreign substrate, lattice mismatched to the semiconductor substrate materials, or on existing (0001) oriented highly dislocated layer of the semiconductor substrate materials, characterized in that
the method comprises the steps of:
growing a dislocation redirection layer on said foreign substrate or said existing highly dislocated layer, the growing providing intentional inclination of threading dislocations towards high index crystallographic planes, having crystallographic indexes other than (0001) and those of the type {1 1̅00}, in order to enhance the probability of the threading dislocations to meet and react with each other; and
growing a dislocation reaction layer above said dislocation redirection layer, the growing facilitating reactions between the threading dislocations, thereby reducing the dislocation density.

8. A method according to claim 7, characterized in that
the growing of said dislocation redirection layer is started with formation of precipitates on the surface of said foreign substrate or said existing highly dislocated layer, said precipitates having a height of 0.1-1.5 μm and surface density of 10⁷-10⁸ cm⁻²; and
the growing of said dislocation reaction layer comprises preferential growing of crystallographic plane facets with crystallographic index (0001).

9. A method according to claim 8, characterized in that said precipitates are formed by a process consisting of a sequence of short low-temperature depositions, performed in temperature range of 450-700° C., followed by high-temperature layer annealing periods, performed in temperature range of 900-1150° C.

10. A method according to claim 8, characterized in that
the growing of said dislocation redirection layer comprises the steps of:
1) formation of said precipitates on the surface of said foreign substrate or said existing highly dislocated layer; and
2) preferential growing of crystallographic plane facets with crystallographic indexes other than (0001) and those of the type {1 1̅00}.

11. A method according to claim 8, characterized in that
the growing of said dislocation redirection layer comprises the steps of
1) formation of said precipitates on the surface of said foreign substrate or said existing highly dislocated layer;
2) preferential growing of crystallographic plane facets with crystallographic indexes other than (0001) and those of the type {1 1̅00};
3) in situ deposition of amorphous material into the surface potential minima located in grooves; and
4) preferential growing of crystallographic plane facets with crystallographic indexes other than (0001) and those of the type {1 1̅00}.

12. A method according to claim 8, characterized in that
the growing of said dislocation redirection layer comprises the steps of
1) formation of said precipitates on the surface of said foreign substrate or said existing highly dislocated layer;
2) preferential growing of crystallographic plane facets with crystallographic index (0001);
3) in situ selective chemical etching of the regions on the layer surface close to the dislocation cores;
4) in situ deposition of amorphous material into the surface potential minima located in the etch pits; and
5) preferential growing of crystallographic plane facets with crystallographic indexes other than (0001) and those of the type {1 1̅00}.

13. A method according to claim 7, characterized in that a dislocation redirection layer having a total thickness of 0.2-4 μm is grown.

14. A method according to claim 7, characterized in that a dislocation reaction layer having a thickness of 1-10 μm is grown.
